(19) United States
(12) Patent Application Publication
(10) Pub. No.: US 2025/0219609 A1
(43) Pub. Date: Jul. 3, 2025

(54) FILM BULK ACOUSTIC RESONATOR

(71) Applicant: AAC ACOUSTIC TECHNOLOGIES (SHENZHEN) CO., LTD., Shenzhen (CN)

(72) Inventors: Shuai Yang, Shenzhen (CN); Zhang Zhang, Shenzhen (CN); Ke Wu, Shenzhen (CN); Lirong Zhang, Shenzhen (CN); Zhiqiang Zhuang, Shenzhen (CN); Chao Wang, Shenzhen (CN)

(21) Appl. No.: 18/791,477

(22) Filed: Aug. 1, 2024

Related U.S. Application Data
(63) Continuation of application No. PCT/CN2023/143538, filed on Dec. 29, 2023.

(51) Int. Cl. H03H 9/02; H03H 9/17

(52) U.S. Cl. CPC H03H 9/02125; H03H 9/173

(57) ABSTRACT

A film bulk acoustic resonator, including: a substrate; an acoustic reflection structure; a bottom electrode; a piezoelectric film; a top electrode; and a raised frame. A spatial region formed by overlapping of the acoustic reflection structure, the bottom electrode, and the piezoelectric film and the top electrode in a thickness direction of the film bulk acoustic resonator is a resonance region, in which the raised frame is arranged, and openings are formed at a side of the raised frame away from the top electrode. The film bulk acoustic resonator can reduce the area ratio of the raised frame in the resonance region and the intensity of the parasitic resonance peak introduced by the raised frame without reducing the Q value of the resonator and without increasing manufacturing process steps.

### TECHNICAL FIELD

The present disclosure relates to the field of resonators, and in particular, to a film bulk acoustic resonator.

### BACKGROUND

A film bulk acoustic resonator is a resonator manufactured using a silicon substrate by means of microelectromechanical systems (MEMS) technology and thin film technology. The film bulk acoustic resonator enables functions such as mirror image elimination, parasitic filtering and channel selection in wireless transceivers, with high quality factors and easy miniaturization.

The main structure of the film bulk acoustic resonator includes a bottom electrode, a piezoelectric layer and a top electrode, and the working principle is as follows: when radio frequency electrical signals are applied to the top electrode and the bottom electrode, a piezoelectric film undergoes mechanical vibration in a longitudinal direction due to the inverse piezoelectric effect, to form bulk acoustic waves. The bulk acoustic waves are converted into electrical signals due to the piezoelectric effect, enabling the selection of different frequency electrical signals. In the related art, the film bulk acoustic resonator is provided with a raised frame (RAF), and the RAF has higher acoustic impedance than a central region. The RAF increases the acoustic impedance mismatch between the central region and the outside of the resonance region such that transverse parasitic acoustic waves, mainly Rayleigh Lamb waves, propagating toward the outside of the resonance region are reflected back to the resonance region at a region boundary. Therefore, the energy leaked at an edge of the resonance region is reduced, and a Q value of the film bulk acoustic resonator is higher.

Since the relationship curve between the resonator Qp and a width of the RAF is periodic, as the width of the RAF increases, the resonator Qp will increase, and an area ratio of the RAF in the resonance region will continuously increase, resulting in an RAF parasitic resonance peak in an frequency band of the resonator away from fs, so that the intensity of the RAF parasitic resonance peak tends to enhance with the increase of the area ratio of the RAF in the resonance region.

### SUMMARY

An object of the present disclosure is to provide a film bulk acoustic resonator, which aims to solve the problem that the intensity of the parasitic resonance peak introduced by the raised frame is excessively high.

In order to achieve the above object, the present disclosure provides a film bulk acoustic resonator, including: a substrate; an acoustic reflection structure arranged at a side of the substrate; a bottom electrode stacked at a side of the acoustic reflection structure away from the substrate; a piezoelectric film stacked at a side of the bottom electrode away from the acoustic reflection structure; a top electrode stacked at a side of the piezoelectric film away from the bottom electrode; and a raised frame arranged at a side of the top electrode away from the piezoelectric film. A spatial region formed by overlapping of the acoustic reflection structure, the bottom electrode, and the piezoelectric film and the top electrode in a thickness direction of the film bulk acoustic resonator is defined as a resonance region. The raised frame is arranged in the resonance region, and openings are formed at a side of the raised frame away from the top electrode.

In some embodiments of the present disclosure, the openings are sequentially arranged along a horizontal extending direction of the raised frame, and a distance between two adjacent openings is greater than a diameter of the opening.

In some embodiments of the present disclosure, the openings are through holes penetrating two opposite sides of the raised frame, and/or the openings are blind holes.

In some embodiments of the present disclosure, the raised frame is annularly arranged adjacent to a periphery of a projection of the resonance region in the thickness direction of the film bulk acoustic resonator, and the openings are formed in at least a portion of the raised frame.

In some embodiments of the present disclosure, cross sections of the openings have shapes of a circle, an ellipse, a rectangle or combinations thereof.

In some embodiments of the present disclosure, a recessed frame adjacent to an inner peripheral wall of the raised frame is formed at a surface of the top electrode.

In some embodiments of the present disclosure, the film bulk acoustic resonator further includes a cantilever beam connected to an outer peripheral wall of the top electrode and extending in a direction away from the piezoelectric film, wherein an air gap is formed between the cantilever beam and the piezoelectric film.

In some embodiments of the present disclosure, the raised frame is provided with at least one cutoff, and the cutoff penetrates through an inner peripheral wall and an outer peripheral wall of the raised frame.

In some embodiments of the present disclosure, a minimum distance from an edge of one of the openings to an edge of the raised frame is an odd multiple of a quarter wavelength of a transverse parasitic acoustic wave.

In some embodiments of the present disclosure, the film bulk acoustic resonator further includes a protective layer stacked between the top electrode and the raised frame.

In some embodiments of the present disclosure, the acoustic reflection structure is a cavity formed inside the substrate, or a cavity formed at a side of the substrate adjacent to the bottom electrode, or a Bragg reflector formed at a surface of the substrate, and when the acoustic reflection structure is a cavity, a projection of the bottom electrode along the thickness direction of the film bulk acoustic resonator is at least partially located outside the acoustic reflection structure.

In general, compared with the related art, the above technical solutions of the present disclosure have the following beneficial effects.

The present disclosure provides a film bulk acoustic resonator, including: the substrate; the acoustic reflection structure arranged at the side of the substrate; the bottom electrode stacked at the side of the acoustic reflection structure away from the substrate; the piezoelectric film stacked at the side of the bottom electrode away from the acoustic reflection structure; the top electrode stacked at the side of the piezoelectric film away from the bottom electrode; and the raised frame arranged at the side of the top electrode away from the piezoelectric film. The spatial region formed by overlapping of the acoustic reflection structure, the bottom electrode, and the piezoelectric film and the top electrode in the thickness direction of the film bulk acoustic resonator is defined as the resonance region. The raised frame is arranged in the resonance region, and openings are formed at the side of the raised frame away from the top electrode. The technical solutions of the present disclosure can reduce the area ratio of the raised frame in the resonance region and the intensity of the parasitic resonance peak introduced by the raised frame without reducing the Q value of the resonator and without increasing the manufacturing process steps.

### BRIEF DESCRIPTION OF DRAWINGS

FIG. 1A is a top view of a film bulk acoustic resonator according to an embodiment of the present disclosure;

FIG. 1B is a cross-sectional view taken along A-A direction of the film bulk acoustic resonator in FIG. 1A;

FIG. 1C is an impedance curve diagram with a RAF parasitic resonance peak of a film bulk acoustic resonator according to an embodiment of the present disclosure;

FIG. 1D is a corresponding data diagram of intensity of a RAF parasitic resonance peak in a film bulk acoustic resonator and different area ratios of the RAF in a resonance region according to some embodiments of the present disclosure;

FIG. 2 is a top view showing a part of a raised frame in a film bulk acoustic resonator being provided with openings according to an embodiment of the present disclosure;

FIG. 3 is a cross-sectional view taken along A-A direction of the film bulk acoustic resonator in FIG. 2;

FIG. 4 is a top view showing a cross section of a raised frame in a film bulk acoustic resonator being provided with oval openings according to an embodiment of the present disclosure;

FIG. 5 is a cross-sectional view taken along A-A direction of the film bulk acoustic resonator in FIG. 4;

FIG. 6 is a top view showing a raised frame in a film bulk acoustic resonator being provided with blind holes according to an embodiment of the present disclosure;

FIG. 7 is a cross-sectional view taken along A-A direction of the film bulk acoustic resonator in FIG. 6;

FIG. 8 is a top view showing a raised frame in a film bulk acoustic resonator being provided with blind holes and through holes according to an embodiment of the present disclosure;

FIG. 9 is a cross-sectional view taken along A-A direction of the film bulk acoustic resonator in FIG. 8;

FIG. 10 is a top view of a recessed frame arranged in a film bulk acoustic resonator according to an embodiment of the present disclosure;

FIG. 11 is a cross-sectional view taken along A-A direction of the film bulk acoustic resonator in FIG. 10;

FIG. 12 is a top view of a film bulk acoustic resonator provided with a cantilever beam according to an embodiment of the present disclosure;

FIG. 13 is a cross-sectional view taken along A-A direction of the film bulk acoustic resonator in FIG. 12;

FIG. 14 is a top view of a raised frame of a film bulk acoustic resonator provided with a cutoff according to an embodiment of the present disclosure;

FIG. 15 is a cross-sectional view taken along A-A direction of the film bulk acoustic resonator in FIG. 14;

FIG. 16 is a top view of a film bulk acoustic resonator provided with a protective layer according to an embodiment of the present disclosure; and

FIG. 17 is a cross-sectional view taken along A-A direction of the film bulk acoustic resonator in FIG. 16.

### DESCRIPTION OF EMBODIMENTS

In order to make the objectives, technical solutions, and advantages of the present disclosure clearer, the present disclosure is described in further detail below with reference to the accompanying drawings and embodiments. It should be understood that specific embodiments described herein are intended only to interpret the present disclosure and not to limit the present disclosure. In specific embodiments, the film bulk acoustic resonator is shown in a rectangular shape as an example. However, in practice, the film bulk acoustic resonator is not limited to be rectangular, and may further be other polygons or ellipses.

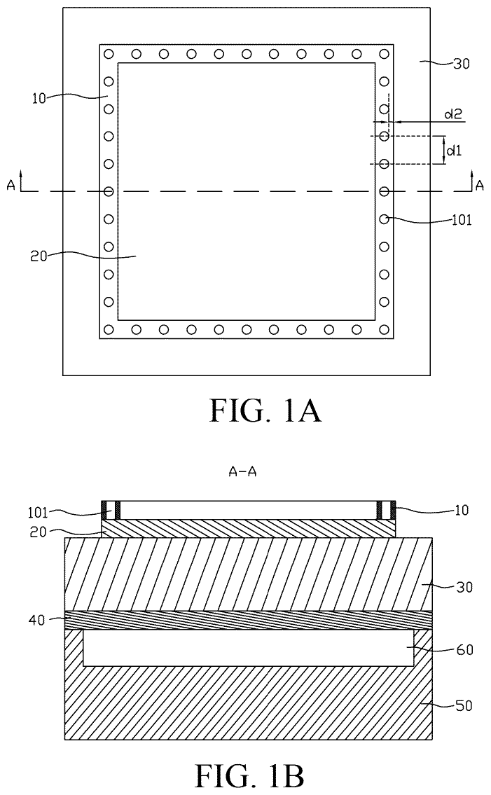

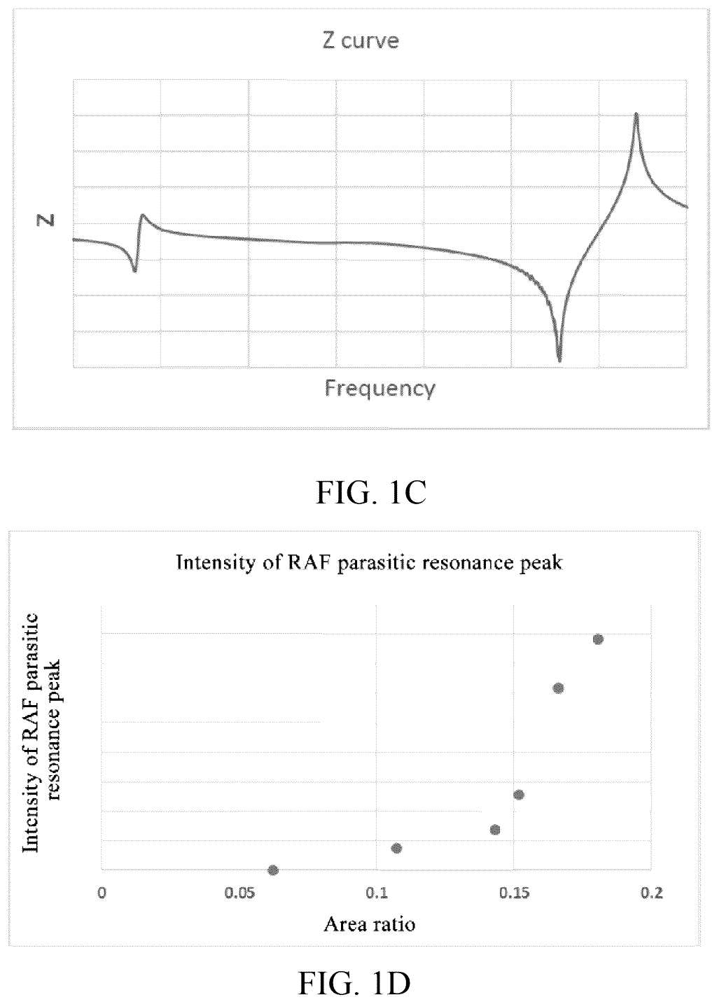

Referring to FIG. 1A and FIG. 1B, the present disclosure provides a film bulk acoustic resonator, including a substrate 50, an acoustic reflection structure 60 arranged at a side of the substrate 50, a bottom electrode 40 stacked at a side of the acoustic reflection structure 60 away from the substrate 50, a piezoelectric film 30 stacked at a side of the bottom electrode 40 away from the acoustic reflection structure 60, a top electrode 20 stacked at a side of the piezoelectric film 30 away from the bottom electrode 40, and a raised frame 10 arranged on a side of the top electrode 20 away from the piezoelectric film 30. The spatial region formed by overlapping the acoustic reflection structure 60, the bottom electrode 40, the piezoelectric film 30, and the top electrode 20 in a thickness direction of the film bulk acoustic resonator is defined as a resonance region, and the raised frame 10 is arranged in the resonance region. A plurality of openings 101 is formed at a side of the raised frame 10 away from the top electrode 20.

Electric energy is applied to the top electrode 20 and the bottom electrode 40 to induce an electric field in the piezoelectric film 30. The electric field will generate an inverse piezoelectric effect in the piezoelectric film 30 to convert the electric energy into mechanical energy. The mechanical energy exists in the form of sound waves, and the sound waves have two vibration modes of transverse wave and longitudinal wave.

In an embodiment, the acoustic reflective structure 60 is a cavity formed inside the substrate 50, or a cavity formed on a side of the substrate 50 adjacent to the bottom electrode 40, or a Bragg reflector formed at a surface of the substrate 50. When the acoustic reflection structure 60 is a cavity, a projection of the bottom electrode 40 along a thickness direction of the film bulk acoustic resonator is at least partially located outside the acoustic reflection structure 60. The acoustic reflection structure 60 of the film bulk acoustic resonator arranged at a side of the substrate 50 allows the acoustic waves to be limited to the cavity of the substrate 50, which significantly reduces acoustic wave energy lose, and thereby effectively improving the performance of the film bulk acoustic resonator. An acoustic reflector may further be a layer structure formed on the surface of the substrate 50, and the layer structure is formed by overlapping a high acoustic impedance layer and a low acoustic impedance layer. The low acoustic impedance layer is silicon oxide, and the high acoustic impedance layer is formed by at least one of tungsten (W), molybdenum (Mo), ruthenium (Ru), iridium (Ir) and other materials.

These bulk acoustic waves are converted into electrical signals under the influence of piezoelectric effect, thereby realizing selection of electrical signals of different frequencies. In the related art, the raised frame 10 is provided in the film bulk acoustic resonator, and the raised frame 10 has a higher acoustic impedance than a central region. The raised frame 10 increases the acoustic impedance mismatch between the central region and the outside of the resonance region such that transverse parasitic acoustic waves, mainly Rayleigh Lamb waves, propagating the outside of the resonance region are reflected back to the resonance region at the boundary of the region. Therefore, the energy leaked at the edge of the resonance region is reduced, and a Q value of the film bulk acoustic resonator is higher.

Referring to FIG. 1C and FIG. 1D, as the width of the RAF increases, the resonator Qp will increase, and an area ratio of the RAF in the resonance region will continuously increase, resulting in a RAF parasitic resonance peak in an frequency band of the resonator away from fs, so that the intensity of the RAF parasitic resonance peak tends to enhance with the increase of the area ratio of the RAF in the resonance region. By using the raised frame 10 with openings 101, the area ratio of the raised frame 10 in the resonance region can be effectively reduced, and the intensity of the RAF parasitic resonance peak caused by the width of the annular raised frame 10 is reduced (as shown in FIG. 3), so that the influence of the large amplitude of the RAF parasitic resonance peak on the performance of a filter of the frequency band is avoided without reducing the Q value of the film bulk acoustic resonator. In addition, the acoustic impedance of the structure of the openings 101 formed in the raised frame 10 is different from the surrounding region, and the difference in the acoustic impedance can enhance the reflection effect on transverse Rayleigh Lamb waves.

Further, the raised frame 10 having the openings 101 may be arranged in at least one of the following positions: at the side of the top electrode 20 away from the piezoelectric film 30, at the side of the bottom electrode 40 away from the piezoelectric film 30, at the side of the top electrode 20 or the bottom electrode 40 facing the piezoelectric film 30, or in the middle of the piezoelectric film 30. All the raised frames 10 are located in the resonance region, and the openings 101 effectively reduce the area ratio of the raised frame 10 in the resonance region, thereby reducing the intensity of the parasitic resonance peak introduced by the raised frame 10.

In an embodiment of the present disclosure, the openings 101 are sequentially arranged along a horizontal extension direction of the raised frame 10. A distance d1 between two adjacent openings 101, which is defined as a distance between geometric centers of the two openings 101, is greater than a diameter d of the openings 101, which indicates that an interval is formed between adjacent openings 101. The portion of the raised frame 10 within the interval plays a role in reflecting the transverse Rayleigh Lamb waves, thereby improving the Q value of the film bulk acoustic resonator.

Further, there is an included angle between a hole wall of the opening 101 of the raised frame 10 and the top electrode 20, with an angle range of 30° to 90°, such as 30°, 60°, 90°, etc. The openings 101 arranged in this way have different shapes, and the included angle between the hole wall and the top electrode 20 indicates that a hole bottom of the openings 101 can be designed as a bent or flat bottom, so that the openings 101 has expansibility and diversity.

In an embodiment, in order to enhance the acoustic impedance of the raised frame 10 and reflect the transverse Rayleigh Lamb waves, the material of the raised frame 10 includes one metal material or one dielectric material, or a combination of one or more of the metal material and the dielectric material. The metal material may be aluminum (Al), platinum (Pt), gold (Au), tungsten (W), tungsten (Mo), ruthenium (Ru), iridium (Ir) or the like, and the dielectric material may be aluminum nitride (AlN), silicon nitride (Si₃N₄) or the like. The raised frame 10 may have a width ranging from 10 nm to 10000 nm, such as 10 nm, 100 nm, 1000 nm, 10000 nm, etc., and a height ranging from 10 nm to 5000 nm, such as 10 nm, 50 nm, 500 nm, 5000 nm, etc.

Further, the openings 101 of the raised frame 10 may be filled with materials different from those in non-through holes 101a regions, such as AlN, SiO₂, SiN, etc.

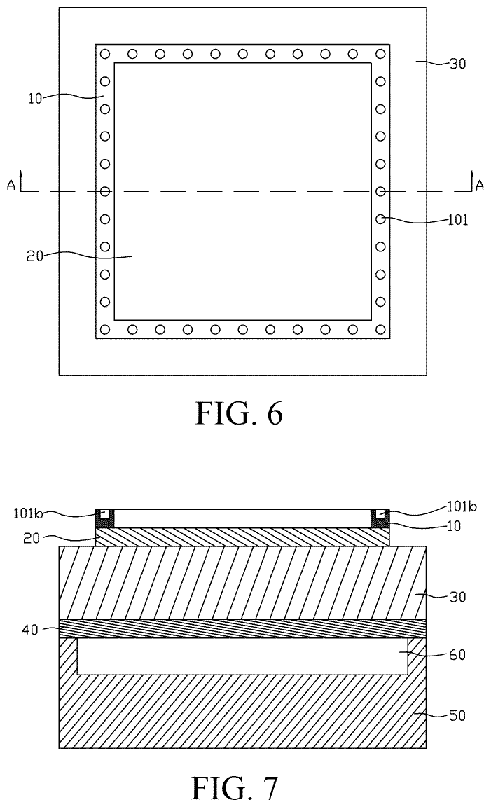

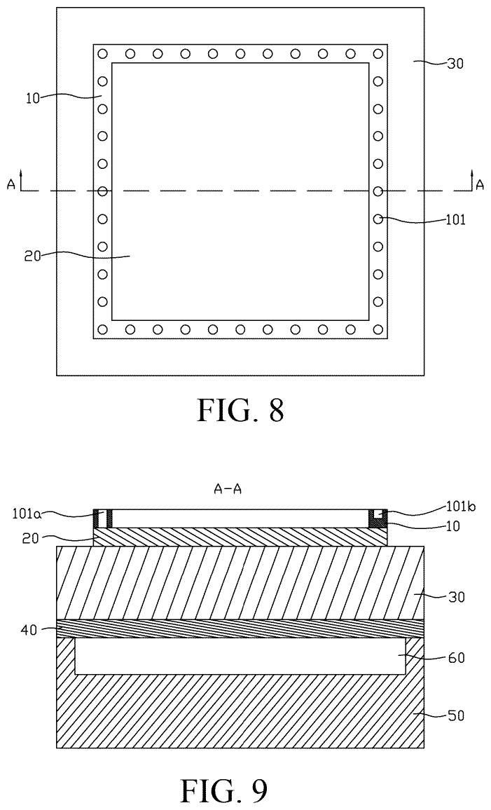

In some embodiments, referring to FIG. 6 to FIG. 9, the openings 101 may be through holes 101a penetrating two opposite sides of the raised frame 10; and/or the openings 101 may be blind holes 101b. An opening direction of the blind holes 101b may be at a side of the raised frame 10 away from the top electrode 20, or at a side of the raised frame 10 facing the top electrode 20. In other embodiments, the raised frame 10 may be provided with a plurality of through holes 101a and a plurality of blind holes 101b at the same time, and the through holes 101a and the blind holes 101b may be combined in a preset manner, so that the area ratio of the raised frame 10 in the resonance region may be adjusted and controlled according to actual demands.

In an embodiment, the raised frame 10 is annularly arranged adjacent to the edge of the projection of the resonance region along a thickness direction of the film bulk acoustic resonator, and each opening 101 is provided at a part on the horizontal extending plane of the raised frame 10. The shape of the raised frame 10 may be rectangular, circular, oval or other polygonal.

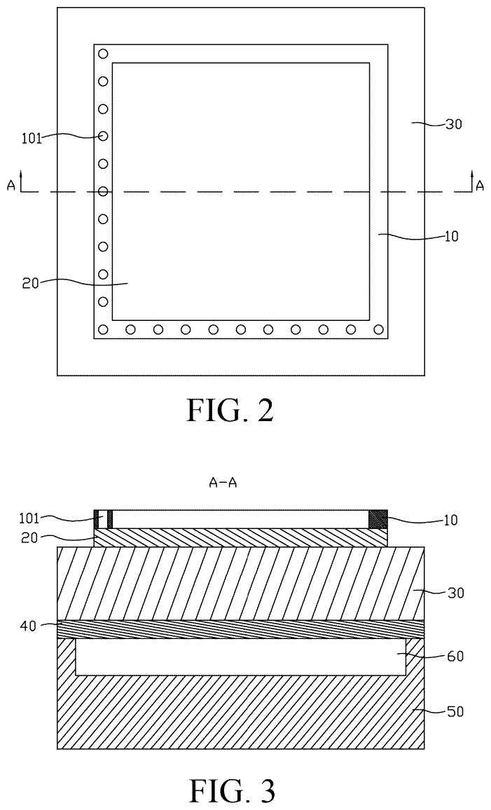

In some embodiments, referring to FIG. 2 and FIG. 3, the openings 101 may be arranged at a periphery of the raised frame 10. For example, when the raised frame 10 is rectangular, the openings 101 may be arranged at each side of the raised frame 10, and a number of the openings 101 at each side may be equal or different. The openings 101 may further be arranged at peripheral regions of the raised frame 10. For example, when the raised frame 10 is rectangular, the openings 101 may be arranged at two adjacent sides of the rectangle. The openings 101 on the raised frame 10 are all arranged at propagation paths of the transverse Rayleigh Lamb waves propagating outside the resonance region. When the raised frame 10 reflects the transverse Rayleigh Lamb waves, the area ratio of the raised frame 10 in the resonance region is reduced, and the intensity of the parasitic resonance peak of the raised frame 10 is reduced. The arrangement of the openings 101 may be arranged along the annular pattern as described above, and the openings may be arranged on part of the raised frame 10 or the entire raised frame 10.

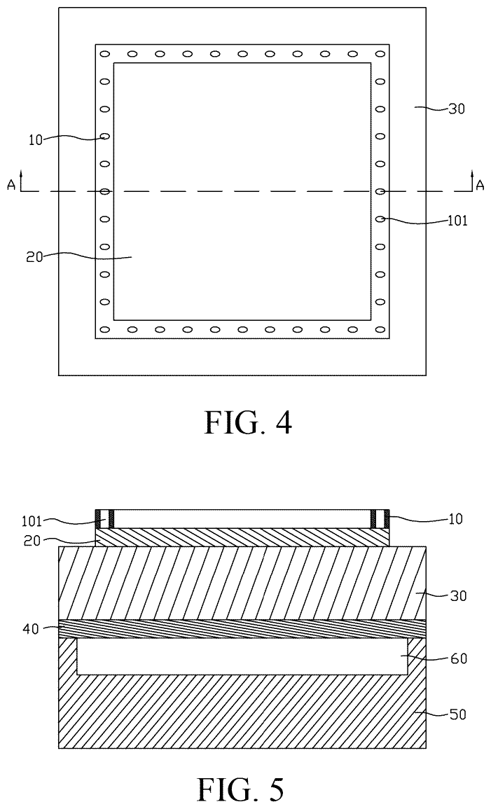

Further, referring to FIG. 4 and FIG. 5, in some embodiments of the present disclosure, a cross section of the openings 101 may be a combination of one or more shapes of a circle, an ellipse, or a rectangle, or another shape capable of reducing an area of the raised frame 10. On this basis, the openings 101 of one shape or a combination of multiple shapes may be the through holes 101a or the blind holes 101b, or a combination of the through holes 101a and the blind holes 101b.

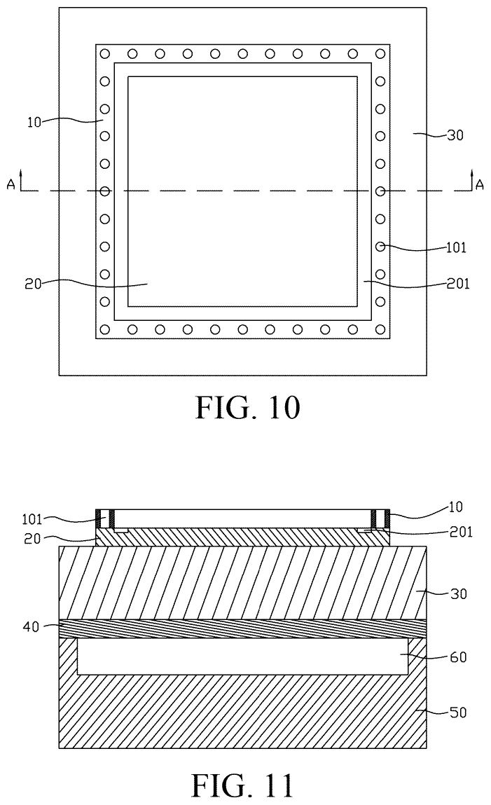

Referring to FIG. 10 and FIG. 11, a recessed frame 201 adjacent to an inner peripheral wall of the raised frame 10 is recessed from the surface of the top electrode 20. The recessed frame 201 can change the acoustic impedance within the resonance region. The acoustic impedance within the recessed frame 201 is different from the acoustic impedance outside the recessed frame 201, and the acoustic impedance provided by the recessed frame 201 is discontinuous. Thus, the acoustic impedance mismatch provided by the recessed frame 201 advantageously improves the performance of the film bulk acoustic resonator. When compared with a conventional film bulk acoustic resonator, incorporating the recessed frame 201 into the film bulk acoustic resonator facilitate reducing the intensity of the parasitic resonance peak introduced by the raised frame 10 in the resonance region of the film bulk acoustic resonator and improving the Q value of the film bulk acoustic resonator.

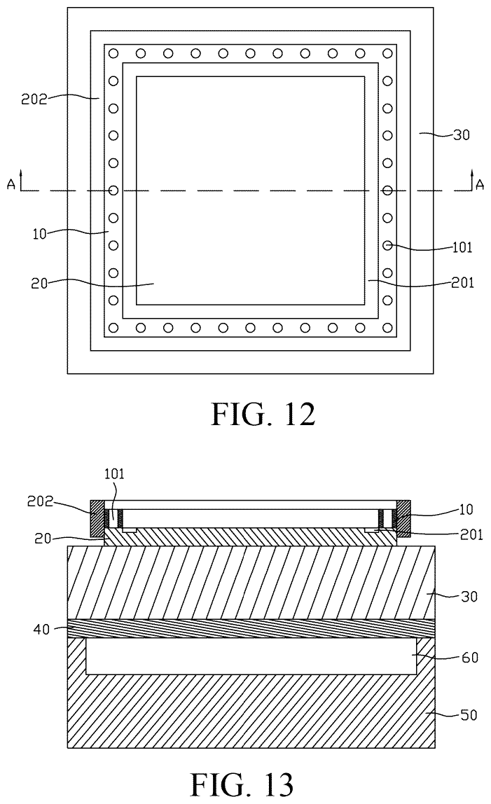

Further, referring to FIG. 12 and FIG. 13, the film bulk acoustic resonator further includes a cantilever beam 202 connected to an outer peripheral wall of the top electrode 20 and extending in a direction away from the piezoelectric film 30, and an air gap is formed between the cantilever beam 202 and the piezoelectric film 30. The cantilever beam 202 can effectively reflect the Q value of a transverse acoustic wave enhancement resonator due to the acoustic impedance mismatch.

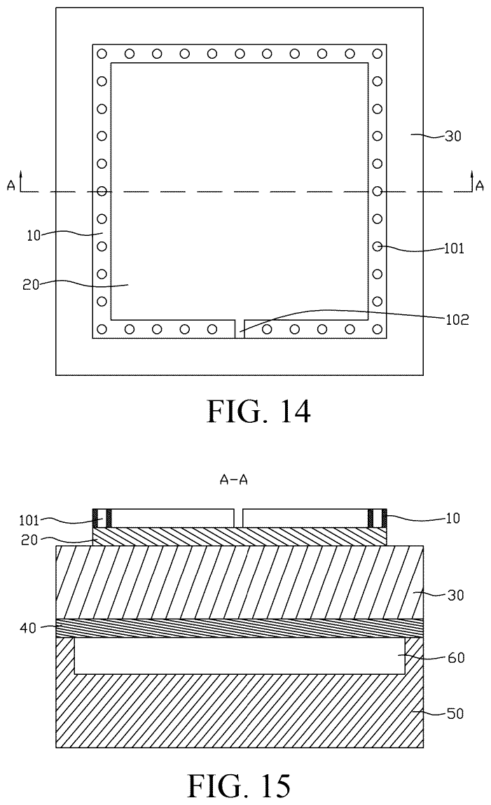

In an embodiment, referring to FIG. 14 and FIG. 15, the raised frame 10 is provided with at least one cutoff 102, and the cutoff 102 penetrates through the inner peripheral wall and the outer peripheral wall of the raised frame 10. An inner side of the raised frame 10 forms a central region of the resonance region, and an outer side of the raised frame 10 forms an outer region of the resonance region. Multiple cutoffs 102 effectively connect the central region and the outer region of the resonance region. The cutoff 102 of the raised frame 10 may not penetrate the inner peripheral wall or the outer peripheral wall, and the depth of the cutout 102 is less than the width of the raised frame 10. The above arrangements all can reduce the area of a raised width, and the intensity of the parasitic resonance peak introduced by the raised frame 10, thereby improving the Q value of the film bulk acoustic resonator.

Further, a nearest distance from a hole edge of the openings 101 to an edge of the raised frame 10 is an odd multiple of a quarter wavelength of the transverse parasitic acoustic waves. The acoustic impedance of the structure of the openings 101 introduced by the raised frame 10 is different from surrounding regions. This acoustic impedance difference can enhance the reflection effect on the transverse Rayleigh Lamb waves, especially when a distance d2 from the openings 101 to the edge of the raised frame 10 is ¼ wavelength of the transverse Rayleigh Lamb waves or odd multiple of the ¼ wavelength, the reflection efficiency of the raised frame 10 on the transverse Rayleigh Lamb waves is highest, and the energy leaked from the edge of the resonance region in this mode is minimum, thereby improving the Q value of the film bulk acoustic resonator.

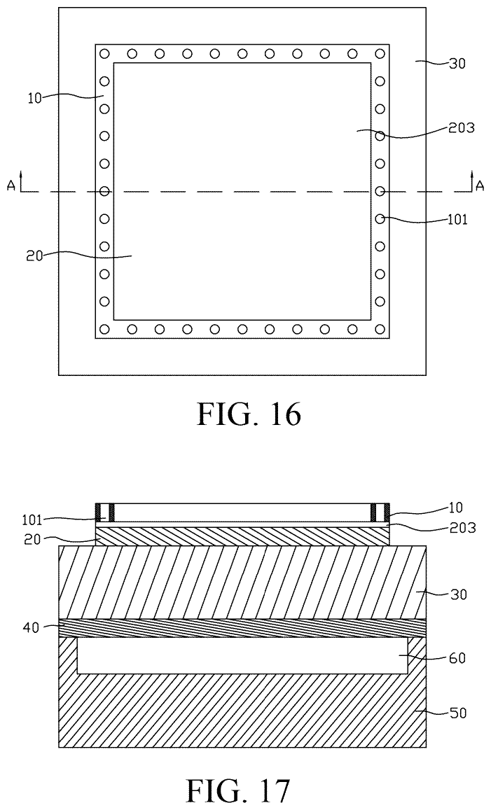

Referring to FIG. 16 and FIG. 17, the film bulk acoustic resonator further includes a protective layer 203 stacked between the top electrode 20 and the raised frame 10. The protective layer 203 is an etched protective layer for protecting the top electrode 20 when etched the raised frame 10 including the structure of the openings 101, and the protective layer 203 is a dielectric material.

The above description illustrates only some embodiments of the present disclosure, and it should be noted that those skilled in the art can also make improvements without departing from the concept of the present disclosure, but these all fall within the protection scope of the present disclosure.

What is claimed is:

1. A film bulk acoustic resonator, comprising:
a substrate;
an acoustic reflection structure arranged at a side of the substrate;
a bottom electrode stacked at a side of the acoustic reflection structure away from the substrate;
a piezoelectric film stacked at a side of the bottom electrode away from the acoustic reflection structure;
a top electrode stacked at a side of the piezoelectric film away from the bottom electrode; and
a raised frame arranged at a side of the top electrode away from the piezoelectric film;
wherein a spatial region formed by overlapping of the acoustic reflection structure, the bottom electrode, the piezoelectric film and the top electrode in a thickness direction of the film bulk acoustic resonator is defined as a resonance region,
the raised frame is arranged in the resonance region, and openings are formed at a side of the raised frame away from the top electrode.

2. The film bulk acoustic resonator as described in claim 1, wherein the openings are sequentially arranged along a horizontal extending direction of the raised frame, and a distance between two adjacent openings is greater than a diameter of the opening.

3. The film bulk acoustic resonator described in claim 2, wherein the openings are through holes penetrating two opposite sides of the raised frame, and/or the openings are blind holes.

4. The film bulk acoustic resonator as described in claim 3, wherein the raised frame is annularly arranged adjacent to a periphery of a projection of the resonance region in the thickness direction of the film bulk acoustic resonator, and the openings are formed in at least a portion of the raised frame.

5. The film bulk acoustic resonator as described in claim 3, wherein cross sections of the openings have shapes of a circle, an ellipse, a rectangle or combinations thereof.

6. The film bulk acoustic resonator as described in claim 1, wherein a recessed frame adjacent to an inner peripheral wall of the raised frame is formed at a surface of the top electrode.

7. The film bulk acoustic resonator as described in claim 6, further comprising a cantilever beam connected to an outer peripheral wall of the top electrode and extending in a direction away from the piezoelectric film, wherein an air gap is formed between the cantilever beam and the piezoelectric film.

8. The film bulk acoustic resonator as described in claim 1, wherein the raised frame is provided with at least one cutoff, and the cutoff penetrates through an inner peripheral wall and an outer peripheral wall of the raised frame.

9. The film bulk acoustic resonator as described in claim 1, wherein a minimum distance from an edge of one of the openings to an edge of the raised frame is an odd multiple of a quarter wavelength of a transverse parasitic acoustic wave.

10. The film bulk acoustic resonator as described in claim 1, further comprising a protective layer stacked between the top electrode and the raised frame.

11. The film bulk acoustic resonator as described in claim 1, wherein the acoustic reflection structure is a cavity formed inside the substrate, or a cavity formed at a side of the substrate adjacent to the bottom electrode, or a Bragg reflector formed at a surface of the substrate, and when the acoustic reflection structure is a cavity, a projection of the bottom electrode along the thickness direction of the film bulk acoustic resonator is at least partially located outside the acoustic reflection structure.
